(19) United States
(12) Patent Application Publication
(10) Pub. No.: US 2026/0231725 A1
(43) Pub. Date: Aug. 6, 2026

(54) SEMICONDUCTOR CARRIER

(71) Applicant: Ennostar Corporation, Hsinchu City (TW)

(72) Inventors: Shiou-Yi KUO, Hsinchu City (TW); Tsung-Hao SU, Hsinchu City (TW); Yi-Zhen HUANG, Hsinchu City (TW); Wei-Yuan MA, Hsinchu City (TW)

(21) Appl. No.: 19/465,704

(22) Filed: Jan. 30, 2026

(30) Foreign Application Priority Data
Feb. 3, 2025 (TW) 114103741

(51) Int. Cl. H10P 72/10

(52) U.S. Cl. CPC H10P 72/165

(57) ABSTRACT

A semiconductor carrier is provided. The semiconductor carrier includes a base material, a carrier structure, and a first semiconductor element. The carrier structure is disposed on the base material, wherein the carrier structure has a plurality of contact protrusions arranged in a periodical configuration. The first semiconductor element is disposed on the carrier structure and in a configuration of contacting the plurality of contact protrusions, wherein the first surface of the first semiconductor element has a first surface area SA1, and a first contact area CA1 with the plurality of contact protrusions. The ratio CA1/SA1 satisfies the condition: 0.1≤CA1/SAI<1.

### CROSS REFERENCE TO RELATED APPLICATIONS

This Application claims priority of Taiwan Patent Application No. 114103741, filed on Feb. 3, 2025, the entirety of which is incorporated by reference herein.

### BACKGROUND OF THE INVENTION

### Field of the Invention

The present disclosure relates to The present disclosure relates to semiconductor technology, and, in particular, it relates to a semiconductor carrier.

### Description of the Related Art

In the conventional process for mass transfer of semiconductor structures, the process generally includes the following steps. First, a semiconductor stack is formed on a growth substrate, and bonded to a temporary substrate via a structure such as a supporting structure (also referred to as a weakening structure or a frame structure). Next, the growth substrate is removed, such that the semiconductor stack is transferred onto the temporary substrate. Finally, the supporting structure is fractured to release the semiconductor stack from the temporary substrate and transfer it to a target substrate. In these steps, the fineness of the supporting structure greatly affects the process yield. For example, if the supporting structure has insufficient strength, it may fail to stably support the semiconductor stack. Conversely, if the supporting structure is too strong, it may be difficult to break. Therefore, although conventional mass transfer processes have gradually met their intended purposes, they do not meet requirements in all respects. Therefore, there are still problems to be overcome regarding the technology behind the mass transfer process.

### BRIEF SUMMARY OF THE INVENTION

In some embodiments, a semiconductor carrier is provided. The semiconductor carrier includes a base material, a carrier structure, and a first semiconductor element. The carrier structure is disposed on the base material, wherein the carrier structure has a plurality of contact protrusions arranged in a periodical configuration. The first semiconductor element is disposed on the carrier structure and in a configuration of contacting the plurality of contact protrusions, wherein the first surface of the first semiconductor element has a first surface area SA1, and a first contact area CA1 with the plurality of contact protrusions. The ratio CA1/SA1 satisfies the condition: 0.1≤CA1/SAI<1.

The semiconductor carrier of the present disclosure may be applied in a variety of electronic devices. In order to make the features and advantages of the present disclosure more comprehensible, various embodiments are specially cited hereinafter, collectively with the accompanying drawings, to be described in detail as follows.

### BRIEF DESCRIPTION OF THE DRAWINGS

Aspects of the present disclosure are best understood from the following detailed description when read with the accompanying figures. It should be noted that in accordance with the standard practice in the industry, various features are not drawn to scale. In fact, the dimensions of the various features may be arbitrarily increased or reduced for clarity of discussion.

FIGS. 1 to 9 are schematic diagrams illustrating the semiconductor carrier at different stages in the mass transfer process according to some embodiments of the present disclosure.

FIG. 10A is a perspective view illustrating the contact protrusion according to some embodiments of the present disclosure.

FIG. 10B is a schematic top view illustrating the contact protrusions according to some embodiments of the present disclosure.

FIG. 11A is a schematic top view illustrating the contact protrusions and the first semiconductor element according to some embodiments of the present disclosure.

FIG. 11B is a schematic top view illustrating the contact protrusions and the second semiconductor element according to some embodiments of the present disclosure.

FIG. 11C is a schematic top view illustrating the contact protrusions, the first semiconductor element, and the second semiconductor element according to some embodiments of the present disclosure.

FIGS. 12 to 14 are schematic diagrams illustrating the semiconductor carrier at different stages in the mass transfer process according to other embodiments of the present disclosure.

FIG. 15 is a schematic view illustrating possible arrangements of semiconductor elements according to some embodiments of the present disclosure.

### DETAILED DESCRIPTION OF THE INVENTION

The following disclosure provides many different embodiments or examples for implementing the provided apparatus. Specific examples of various components and their configurations are described below to simplify the embodiments of the present disclosure, but are certainly not intended to limit the present disclosure. For example, if the description mentions that a first component is formed on a second component, it may include an embodiment in which the first component and the second component are in direct contact, and it may also include an embodiment in which an additional component is formed between the first component and the second component so that the first component and the second component are not in direct contact. Furthermore, the present disclosure may repeat element numerals and/or characters in different embodiments or examples. This repetition is for the purpose of brevity and clarity and is not intended to indicate a relationship between the various embodiments and/or examples discussed.

In some embodiments of the present disclosure, terms such as “disposed”, “connected” and the like, unless otherwise defined, may refer to two components being in direct contact, or may refer to two components not being in direct contact, with an additional junction component between the two structures. Terms related to being arranged and connected may also include situations where both structures are movable, or both structures are fixed.

In addition, the terms “first”, “second” and similar terms mentioned in this specification or the scope of the patent application are used to name different components or distinguish different embodiments or scopes, and are not used to limit the upper or lower limit of the number of components, nor are they used to limit the manufacturing order or setting order of the components.

As used herein, the terms “approximate,” “about,” and “substantially” generally mean within 10%, or within 5%, or within 3%, or within 2%, or within 1%, or within 0.5% of a given value or range. The quantities given here are approximate quantities, that is, even if there is no specific description of “about”, “approximately”, or “substantially”, the meanings of “about”, “approximately”, or “substantially” may still be implied. The term “a range between a first value and a second value” means that the range includes the first value, the second value, and other values therebetween. Furthermore, there may be a certain error between any two values or directions used for comparison. If a first value is equal to a second value, it implies that there may be an error of about 10%, or within 5%, or within 3%, or within 2%, or within 1%, or within 0.5% between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

It should be understood that, for the sake of clarity, some elements of the device are omitted in the drawings, and only some elements are schematically illustrated. In some embodiments, additional components may be added to the devices described below. In other embodiments, some of the components of the apparatus described below may be replaced or omitted. It should be understood that in some embodiments, additional operating steps may be provided before, during and/or after the device manufacturing method. In some embodiments, some of the operation steps described may be replaced or omitted, and the order of some of the operation steps described may be interchangeable.

Unless otherwise defined, all terms (including technical and scientific terms) used herein have the same meanings as commonly understood by one of ordinary skill in the art. It is understood that these terms, such as those defined in commonly used dictionaries, should be interpreted as having meanings consistent with the background or context of the relevant technology and the present disclosure, and should not be interpreted in an idealized or overly formal manner unless specifically defined in the embodiments of the present disclosure.

In the conventional process for mass transfer of semiconductor structures, a supporting structure is typically used to bond the semiconductor stack to a temporary substrate. However, the fabrication of such supporting structures not only increase the complexity of the process, but also significantly affects the process yield due to the precision required in their structure. To address these issues, the present disclosure provides a semiconductor carrier, which includes a base material, a carrier structure, and a semiconductor element. Specifically, the base material and the carrier structure collectively form a temporary substrate, which can not only temporarily attach the semiconductor element, but also has the benefit of easily picking up the semiconductor element. In this way, some of the problems, such as high process complexity and low process yield in the prior art, can be effectively solved.

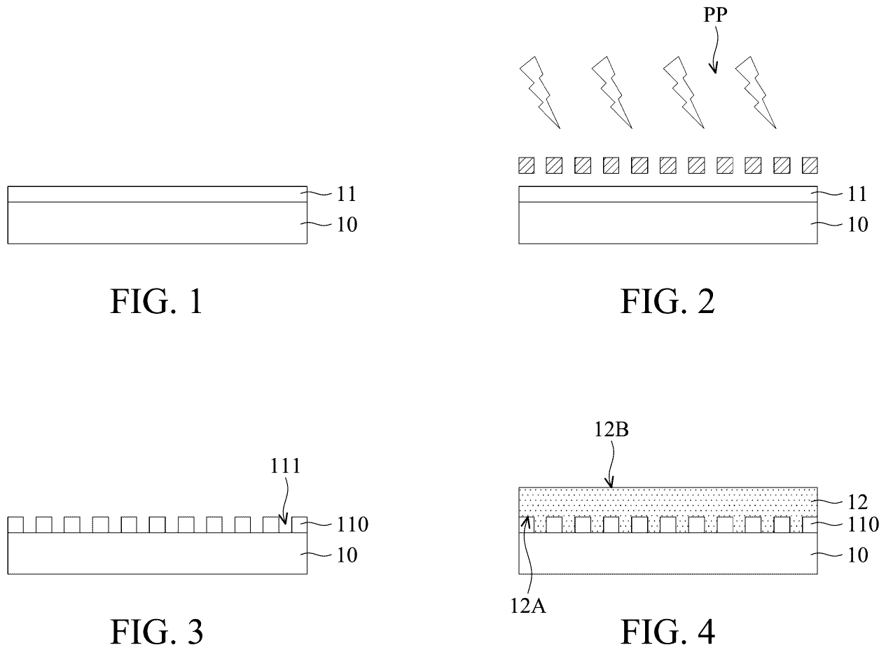

FIGS. 1 to 9 are schematic diagrams illustrating the semiconductor carrier 1 at different stages in the mass transfer process according to some embodiments of the present disclosure. Specifically, the semiconductor carrier 1 includes a base material, a carrier structure and a semiconductor element. Among them, FIGS. 1 to 6 are about the manufacturing method of the carrier structure, and FIGS. 7 to 9 are about the steps of transferring the semiconductor element from the base material to the target substrate by means of the carrier structure.

As shown in FIG. 1, a substrate 10 is provided. In some embodiments, the material of the substrate 10 may be or may include: Group IV elements or Group IV compounds, such as silicon (Si), diamond (C) or silicon carbide (SiC); Group III-V compounds, such as gallium nitride (GaN), aluminum gallium nitride (AlGaN), aluminum nitride (AlN), gallium phosphide (GaP), gallium arsenide (GaAs), or aluminum gallium arsenide (AlGaAs); other suitable materials; or combinations thereof, but the present disclosure is not limited thereto. In some embodiments, the material of the substrate 10 may be or may include glass, quartz, sapphire, ceramic, other suitable materials, or combinations thereof, but the present disclosure is not limited thereto. In some embodiments, the material of the substrate 10 may be or may include polyimide (PI), polycarbonate (PC), polyethylene terephthalate (PET), polypropylene (PP), other suitable materials, or combinations thereof, but the present disclosure is not limited thereto.

Following the above steps, a photoresist material 11 is disposed on the substrate 10. In some embodiments, the photoresist material 11 may be a positive photoresist or a negative photoresist. In some embodiments, the photoresist material 11 may completely cover the entire upper surface of the substrate 10. However, the present disclosure is not limited thereto. In other embodiments, the photoresist material 11 may selectively cover a portion of the upper surface of the substrate 10 and expose another portion of the substrate 10.

As shown in FIGS. 2 and 3, following the above steps, a patterning process PP is performed to remove a portion of the photoresist material 11 to form a plurality of protrusions 110. For example, the protrusion 110 may be formed by disposing and patterning the photoresist material 11 through photoresist coating (e.g., spin-on coating), soft baking, mask aligning, exposure, post-exposure baking, photoresist developing, rinsing, drying (e.g., spin-drying and/or hard baking), other suitable steps, or combinations thereof. In some embodiments, the protrusion 110 may be a shaped protrusion.

In some embodiments, the protrusions 110 collectively form a plurality of through vias 111, and the through vias 111 expose the substrate 10. However, the present disclosure is not limited thereto. In other embodiments, the protrusions 110 may also collectively form a plurality of blind vias, and the blind vias do not expose the substrate 10. In some embodiments, the protrusions 110 have a uniform size and pitch, so that the resulting through vias or blind vias also exhibit a uniform size and pitch. However, the present disclosure is not limited thereto.

As shown in FIG. 4, following the above steps, a dielectric material 12 is disposed on the photoresist material 11. Specifically, the dielectric material 12 is blanketly disposed on the photoresist material 11 and filled into the through vias 111 (or blind vias) between adjacent protrusions 110. For example, the dielectric material 12 may be disposed on the photoresist material 11 by a coating process, other suitable processes, or combinations thereof, but the present disclosure is not limited thereto.

In some embodiments, the dielectric material 12 may be or may include polydimethylsiloxane (PDMS), other suitable materials, precursors thereof, or combinations thereof, but the present disclosure is not limited thereto. For example, the dielectric material 12 may include a main agent A and a curing agent B, wherein the main agent A may be poly (dimethyl-methylvinylsiloxane) and the curing agent B may be poly(dimethyl-methylhydrogensiloxane). In some embodiments, the ratio between the main agent A and the curing agent B may be between 10:1 and 30:1, but the present disclosure is not limited thereto. For example, the ratio between the main agent A and the curing agent B may be 10:1, 15:1, 20:1, 30:1, or any value or range therebetween. By adjusting the ratio between the main agent A and the curing agent B, the characteristics of the carrier structure 13 formed from the dielectric material 12 may be modified accordingly.

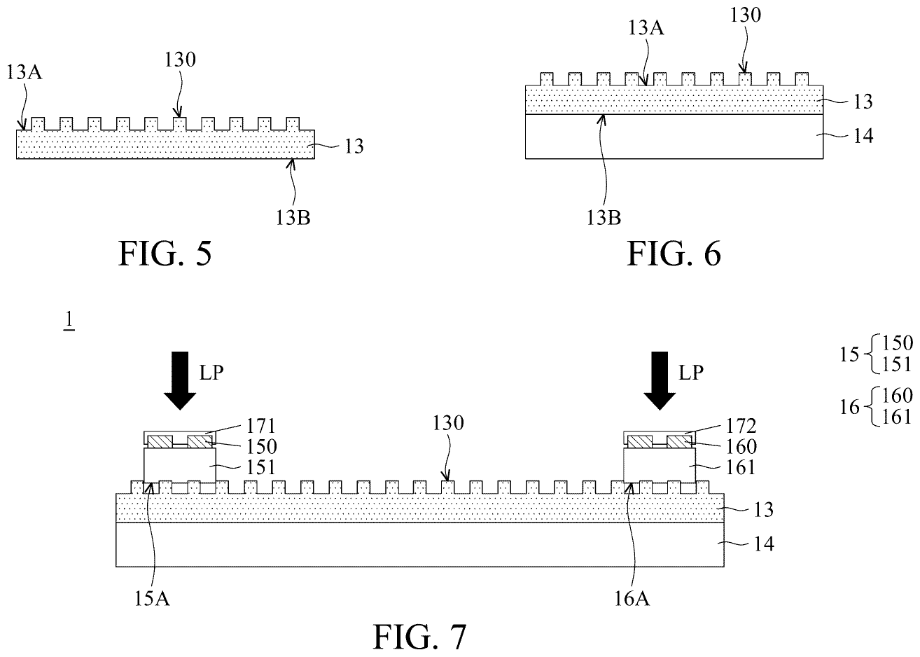

As shown in FIGS. 4 and 5, following the above steps, the dielectric material 12 is cured to obtain a carrier structure 13, wherein the carrier structure 13 has a first surface 13A (i.e., an original bottom surface 12A of the dielectric material 12) and a second surface 13B (i.e., an original top surface 12B of the dielectric material 12). Following the above steps, the substrate 10 is removed and the carrier structure 13 is inverted. The first surface 13A of the carrier structure 13 has a plurality of contact protrusions 130 corresponding to the protrusions 110.

It should be noted that in the present disclosure, the contact protrusions 130 are used to support and adhere to the semiconductor elements during the mass transfer process. Therefore, the material and structure of the contact protrusions 130 need to be controlled to impart specific physical properties. For example, in some embodiments, the carrier structure 13 may be or may include polydimethylsiloxane (PDMS). Accordingly, the elastic recovery or surface adhesion of the contact protrusion 130 may be adjusted by varying the ratio of the main agent A to the cross-linking agent B in the dielectric material 12.

In some embodiments, the contact protrusions 130 are elastic bodies, and the elastic recovery of the contact protrusions 130 is between 5% and 50%. For example, the elastic recovery of the contact protrusions 130 may be 5%, 10%, 15%, 20%, 25%, 35%, 45%, 50%, or any value or range therebetween, but the present disclosure is not limited thereto. As used herein, the term “elastic recovery” refers to the ratio of the recovered height to the compressed height of the contact protrusion 130 after receiving a semiconductor element (the recovery amount of the height of the contact protrusion 130 divided by the compression amount of the height of the contact protrusion 130). For example, the compression amount of the contact protrusion 130 at the time of receiving the semiconductor element is x, and the compression amount of the contact protrusion 130 after a period of time is y, such that x>y due to rebound. The compression amount represents the change in the initial height of the contact protrusion 130 minus the height after compression. As mentioned above, the recovery amount is defined as (x−y), and the elastic recovery is defined as (x−y)/x. If the elastic recovery of the contact protrusion 130 is too low (e.g., less than 5%), the carrier structure 13 may not effectively release the absorbed kinetic energy. Conversely, if the elastic recovery of the contact protrusion 130 is too high (e.g., greater than 50%), the carrier structure 13 may undesirably eject the semiconductor element.

In some embodiments, the contact protrusions 130 has a surface adhesion of between 6 gram-force and 60 gram-force, but the present disclosure is not limited thereto. For example, the surface adhesion of the contact protrusions 130 may be 6.5 gf, 10.0 gf, 15.0 gf, 25.0 gf, 35.0 gf, 45.0 gf, 50.0 gf, 60.0 gf, or any value or range therebetween. If the surface adhesion of the contact protrusions 130 is too low (e.g., less than 6.0 gf), the carrier structure 13 may not be able to effectively adhere to the semiconductor element. Conversely, if the surface adhesion of the contact protrusions 130 is too high (e.g., greater than 60.0 gf), it may be difficult to detach the semiconductor element from the carrier structure 13.

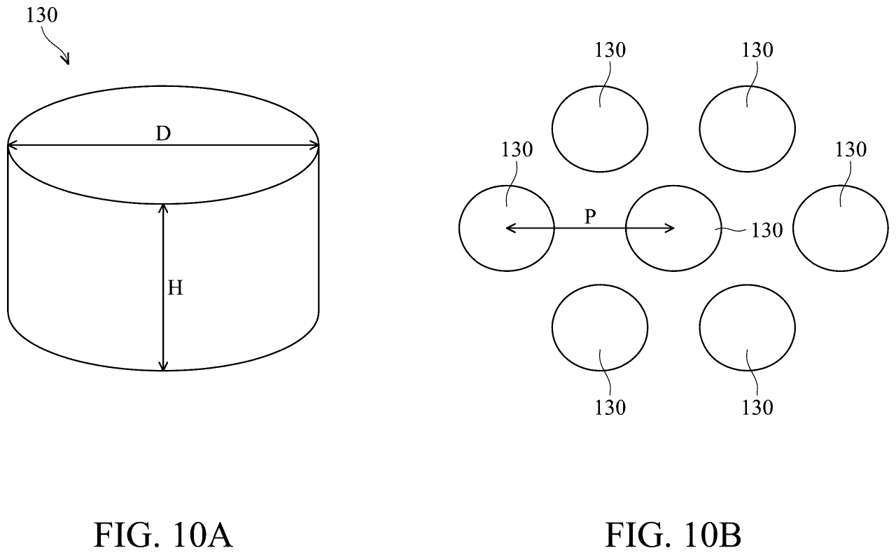

In addition, the shape and size of the contact protrusions 130 may be similar to or the same as those of the through vias 111. Accordingly, the shape and size of the contact protrusions 130 may be adjusted by varying the dimensions of the protrusions 110 or the through vias 111. FIGS. 10A and 10B are a three-dimensional schematic diagram and a top schematic diagram illustrating the contact protrusions according to some embodiments of the present disclosure. As shown in FIG. 10A, in some embodiments, the contact protrusions 130 may have a columnar structure, but the present disclosure is not limited thereto. For example, the contact protrusions 130 may have a cylindrical structure, a triangular prism structure, a rectangular prism structure, a polygonal prism structure, or other suitable shapes. In some embodiments, the diameter D of the contact protrusions 130 is between 0.5μm and 10μm, but the present disclosure is not limited thereto. For example, the diameter D of the contact protrusions 130 may be 0.5 μm, 1 μm, 2 μm, 3 μm, 4 μm, 5 μm, 6 μm, 7 μm, 8 μm, 9 μm, 10 μm, or any value or range therebetween. In some embodiments, the height H of the contact protrusions 130 is between 1 μm and 10 μm, but the present disclosure is not limited thereto. For example, the height H of the contact protrusions 130 may be 1 μm, 2 μm, 3 μm, 4 μm, 5 μm, 6 μm, 7 μm, 8 μm, 9 μm, 10 μm, or any value or range between the above values. In some embodiments, the height-to-width ratio (i.e., height H/diameter D) of the contact protrusions 130 may be between 0.5 and 1.5. For example, the height-to-width ratio of the contact protrusions 130 may be 0.5, 0.6, 0.7, 0.8, 0.9, 1.0, 1.1, 1.2, 1.3, 1.4, 1.5 or any value or range therebetween. In some embodiments, at least one of the plurality of contact protrusions 130 is formed in a cylindrical structure with a height-to-width ratio between 0.5 and 1.5.

In some embodiments, the top surfaces of the contact protrusions 130 are flat, but the present disclosure is not limited thereto. In some embodiments, the width of each contact protrusion 130 may vary from the top surface toward the bottom surface. For example, the contact protrusions 130 may be a columnar structure that is wide at the bottom and narrow at the top, a columnar structure that is narrow at the bottom and wide at the top, a columnar structure with a step-shaped cross section, a columnar structure that is wide at the top and bottom and narrow in the middle, or a columnar structure that is narrow at the top and bottom and wide in the middle. In some embodiments, the sizes, shapes, or intervals of the contact protrusions 130 may be different. For example, the contact protrusion 130 that is adjacent to a side edge of the carrier structure 13 may have a larger size (e.g., a larger diameter), and the contact protrusion 130 that is adjacent to a center portion of the carrier structure 13 may have a smaller size (e.g., a smaller diameter). Alternatively, the contact protrusions 130 may be arranged in the order of a cylindrical structure, a rectangular prism structure, a cylindrical structure, a rectangular prism structure, or in any order. In some embodiments, the contact protrusion 130 that is adjacent to the side edge of the carrier structure 13 may have smaller size (e.g., smaller diameter), and the contact protrusion 130 that is adjacent to the center portion of the carrier structure 13 may have larger size (e.g., larger diameter).

As shown in FIG. 10B, in some embodiments, the contact protrusions 130 are periodically arranged in a hexagonal closest-packed (HCP) configuration. However, the present disclosure is not limited thereto. In some embodiments, the pitch P, defined as the distance between the geometric centers of two adjacent contact protrusions 130, may be between 8 μm and 17.5 μm. In some embodiments, the two adjacent contact protrusions 130 of the plurality of contact protrusions 130 are distant from each other by a pitch of between 8 μm and 17.5 μm. For example, the pitch P may be 8 μm, 9 μm, 10 μm, 11 μm, 12 μm, 13 μm, 14 μm, 15 μm, 16 μm, 17 μm, or any value or range therebetween.

For example, the pitch P between the geometric centers of two adjacent contact protrusions 130 may be 8 μm, 9 μm, 10 μm, 11 μm, 12 μm, 13 μm, 14 μm, 15 μm, 16 μm, 17 μm, or any value or range therebetween. If the pitch P is too small (e.g., less than 0.5 μm), the number of contact protrusions 130 may be excessive, which may hinder the release of the semiconductor element from the carrier structure 13. Conversely, if the pitch P is too large (e.g., greater than 18 μm), the number of contact protrusions 130 may be insufficient, potentially resulting in unstable adhesion of the semiconductor element to the carrier structure 13.

As shown in FIG. 6, following the above steps, a base material 14 is provided. In some embodiments, the material of the base material 14 may be or may include: Group IV elements or Group IV compounds, such as silicon (Si), diamond (C) or silicon carbide (SiC); Group III-V compounds, such as gallium nitride (GaN), aluminum gallium nitride (AlGaN), aluminum nitride (AlN), gallium phosphide (GaP), gallium arsenide (GaAs) or aluminum gallium arsenide (AlGaAs); other suitable materials; or combinations thereof, but the present disclosure is not limited thereto. In some embodiments, the material of the base material 14 may be or may include glass, quartz, sapphire, ceramic, other suitable materials or combinations thereof, but the present disclosure is not limited thereto. In some embodiments, the material of the base material 14 may be or may include polyimide (PI), polycarbonate (PC), polyethylene terephthalate (PET), polypropylene (PP), other suitable materials or combinations thereof, but the present disclosure is not limited thereto. In some embodiments, the material of the base material 14 may be similar to or the same as the material of the substrate 10, but the present disclosure is not limited thereto.

As shown in FIG. 6, following the above steps, the second surface 13B of the carrier structure 13 is bonded to the base material 14, such that the periodically arranged contact protrusions 130 of the carrier structure 13 face away from the base material 14. Through this arrangement, a temporary substrate may be formed (i.e., a combination of the carrier structure 13 and the base material 14), which temporarily supports semiconductor elements and facilitates their detachment during a subsequent laser transfer process.

As shown in FIG. 7, following the above steps, a first semiconductor element 15 is disposed on the carrier structure 13, and the first semiconductor element 15 is in contact with the contact protrusions 130. For example, the first semiconductor element 15 may be disposed on the carrier structure 13 by a laser transfer process LP, but the present disclosure is not limited thereto. During the transfer process, the first semiconductor element 15 impacts the contact protrusions 130, thereby compressing the contact protrusions 130. Accordingly, as previously described, the contact protrusions 130 are preferably configured to meet certain criteria, such as specific adhesion, elastic recovery, arrangement pattern, and packing density, to more reliably receive the first semiconductor element 15. In some embodiments, the first semiconductor element 15 is in direct contact with the contact protrusions 130.

In some embodiments, the first semiconductor element 15 has a first electrode 150 and a first semiconductor stack 151, wherein the first semiconductor stack 151 is located between the first electrode 150 and the contact protrusion 130. In other words, the first electrode 150 of the first semiconductor element 15 faces away from the contact protrusion 130, that is, faces upward. In addition, an adhesive layer 171 may be attached to the first semiconductor element 15, and the adhesive layer 171 is located on a side of the first semiconductor element 15 away from the carrier structure 13. Specifically, the adhesive layer 171 is disposed on the first electrode 150. In some embodiments, the adhesive layer 171 may be or may include laser transfer adhesive, which is used to temporarily connect the first semiconductor element 15 to a growth substrate (not shown) or a temporary substrate (not shown). In such a case, the adhesive layer 171 may lose its adhesion properties through heating, ultraviolet (UV) irradiation, other suitable methods, or combinations thereof, thereby enabling the transfer of the first semiconductor element 15 from the growth substrate or temporary substrate to the carrier structure 13.

In some embodiments, the first semiconductor element 15 may include a light-emitting diode, such as a sub-millimeter light-emitting diode (mini LED), a micro LED, or a quantum dot LED, but the present disclosure is not limited thereto. In some embodiments, the first semiconductor element 15 may include an integrated circuit, such as a micro integrated circuit (μ-IC), but the present disclosure is not limited thereto.

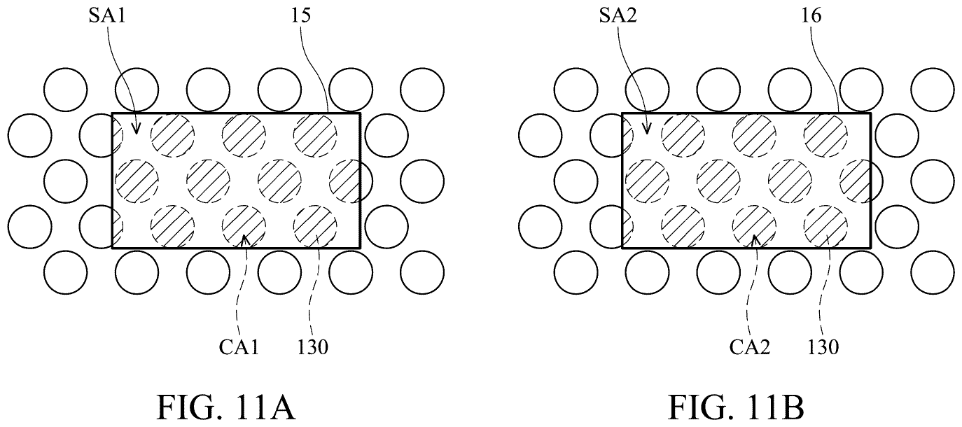

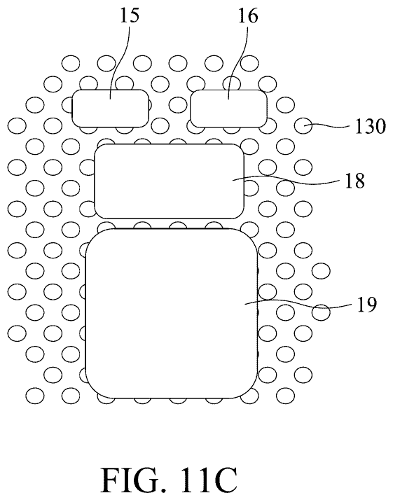

FIG. 11A is a schematic top view showing the contact protrusions and the first semiconductor element according to some embodiments of the present disclosure. As shown in FIG. 11A, in some embodiments, the first semiconductor element 15 is in contact with at least two of the contact protrusions 130. For example, the first semiconductor element 15 may be in contact with two, three, four, or more of the contact protrusions 130, thereby distributing the impact more effectively across multiple contact protrusions 130.

As shown in FIGS. 7 and 11A, in some embodiments, the first surface 15A of the first semiconductor element 15 has a first surface area SA1, and a first contact area CA1. The first contact area CA1 is defined as the area between the first surface 15A of the first semiconductor element 15 and the contact protrusions 130. As used herein, the term “first contact area CA1” refers to the total contact area formed between the first surface 15A and all the contact protrusions 130 that are in contact with the first surface 15A of the first semiconductor element 15. In some embodiments, the first surface 15A of the first semiconductor element 15 has the first surface area SA1, and the first contact area CA1 with the plurality of contact protrusions 130. For example, as illustrated in FIG. 11A, the first semiconductor element 15 may contact twelve contact protrusions 130, and the contact area CA1 corresponds to the sum of the contact areas between the first semiconductor element 15 and those twelve contact protrusions 130. In some embodiments, the ratio CA1/SA1 satisfies 0.1≤CA1/SA1<1. For example, CA1/SA1 may be 0.2, 0.3, 0.4, 0.5, 0.6, 0.7, 0.8, 0.9, or any value or range therebetween, but the present disclosure is not limited thereto. In other words, the first surface 15A is not entirely covered by the contact protrusions 130, and at least 10% of its surface area is in contact with the contact protrusions 130. As described above, if the contact area between the first semiconductor element 15 and the contact protrusions 130 is too small, the carrier structure 13 may not stably retain the semiconductor element. Conversely, if the contact area between the first semiconductor element 15 and the contact protrusions 130 is too large, the semiconductor element may become difficult to detach from the carrier structure 13.

As shown in FIG. 7, in some embodiments, a second semiconductor element 16, which is different from the first semiconductor element 15, may optionally be disposed on the carrier structure 13 via a laser transfer process (LP), such that the second semiconductor element 16 is in contact with the contact protrusions 130. In other words, the temporary substrate of the present disclosure (i.e., the combination of the base material 14 and the carrier structure 13) may be utilized to simultaneously support different types of semiconductor elements, thereby enhancing the versatility of the temporary substrate. In some embodiments, the second semiconductor element 16 is in direct contact with the contact protrusions 130.

In some embodiments, the second semiconductor element 16 has a second electrode 160 and a second semiconductor stack 161, wherein the second semiconductor stack 161 is located between the second electrode 160 and the contact protrusion 130. In other words, the second electrode 160 of the second semiconductor element 16 faces away from the contact protrusion 130, that is, faces upward. Similarly, an adhesive layer 172 may be attached to the second semiconductor element 16. Specifically, the adhesive layer 172 is disposed on the second electrode 160. In some embodiments, the adhesive layer 172 may be or may include laser transfer adhesive, which is used to temporarily connect the second semiconductor element 16 to a growth substrate (not shown) or a temporary substrate (not shown). In such a case, the adhesive layer 172 may lose its adhesion properties through heating, ultraviolet (UV) irradiation, other suitable methods, or combinations thereof, thereby enabling the transfer of the second semiconductor element 16 from the growth substrate or temporary substrate to the carrier structure 13. In some embodiments, the adhesive layer 172 may be similar or identical to the adhesive layer 171, but the present disclosure is not limited thereto.

In some embodiments, the second semiconductor element 16 may include a light-emitting diode, such as a sub-millimeter light-emitting diode (mini LED), a micro light-emitting diode (μLED), or a quantum dot light-emitting diode (QDLED), but the present disclosure is not limited thereto. In some embodiments, the second semiconductor element 16 may include an integrated circuit, such as a micro-integrated circuit (μ-IC), but the present disclosure is not limited thereto.

FIG. 11B is a schematic top view illustrating the contact protrusions and the second semiconductor element according to some embodiments of the present disclosure. As shown in FIG. 11B, in some embodiments, the second semiconductor element 16 is in contact with at least two of the contact protrusions 130. For example, the second semiconductor element 16 is in contact with two, three, four, or more of the contact protrusions 130, thereby distributing the impact more effectively across multiple the contact protrusions 130.

As shown in FIGS. 7 and 11B, similar to the first semiconductor element 15, the second surface 16A of the second semiconductor element 16 has a second surface area SA2, and a second contact area CA2. The second contact area CA2 is defined as the area between the second surface 16A of the second semiconductor element 16 and the contact protrusion 130, wherein the ratio CA2/SA2 satisfies 0.1≤CA2/SA2<1. For example, the ratio CA2/SA2 may be 0.2, 0.3, 0.4, 0.5, 0.6, 0.7, 0.8, 0.9, or any value or range therebetween, but the present disclosure is not limited thereto. In other words, the second surface 16A is not entirely covered by the contact protrusions 130, and at least 10% of the surface area is in contact with the contact protrusions 130. In some embodiments, the second surface 16A of the second semiconductor element 16 has the second surface area SA2, and the second contact area CA2 with the plurality of contact protrusions 130.

FIG. 11C is a schematic top view illustrating the contact protrusions, the first semiconductor element, and the second semiconductor element according to some embodiments of the present disclosure. As shown in FIG. 11C, in some embodiments, the size of the first semiconductor element 15 may be different from the size of the second semiconductor element 16. In this case, the number of contact protrusions 130 that are in contact with the first semiconductor element 15 may be different from the number of contact protrusions 130 that are in contact with the second semiconductor element 16. In some embodiments, the carrier structure 13 may further support a third semiconductor element 18 and a fourth semiconductor element 19, and the third semiconductor element 18 and the fourth semiconductor element 19 may be different from the first semiconductor element 15 and the second semiconductor element 16. In other words, the carrier structure 13 disclosed in the present disclosure may be used to support various semiconductor elements and is not limited by the size or shape of the semiconductor elements.

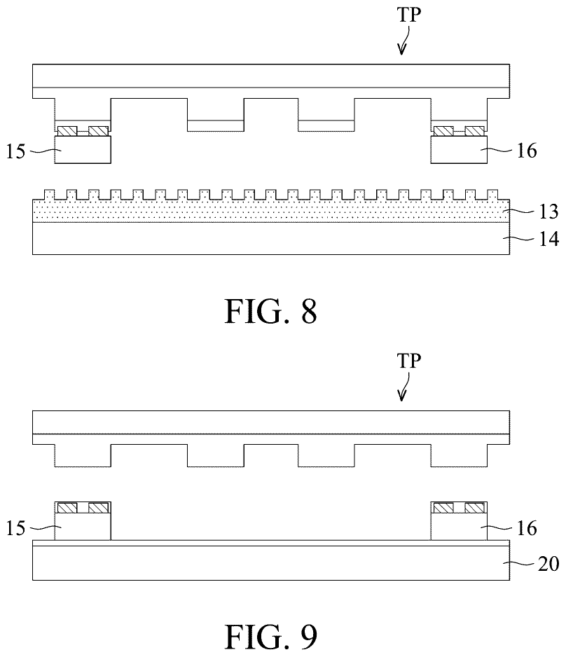

As described above, the present disclosure provides a semiconductor carrier 1 including the base material 14, the carrier structure 13, and the first semiconductor element 15. The semiconductor carrier 1 may optionally further include the second semiconductor element 16, the third semiconductor element 18, and the fourth semiconductor element 19, each being different from the first semiconductor element 15. Compared to conventional mass transfer technologies, the use of contact protrusions 130 of the carrier structure 13 to temporarily support semiconductor elements significantly reduces process complexity and relaxes the precision requirements of the components, thereby addressing certain limitations of the prior art. The following description, with reference to FIGS. 8 and 9, further illustrates the application of the semiconductor carrier 1 in a mass transfer process.

As shown in FIG. 8, following the above steps, the first semiconductor element 15 disposed on the carrier structure 13 is picked up. For example, the first semiconductor element 15 may be picked up from the carrier structure 13 by a stamp transfer process, although the present disclosure is not limited thereto. Similarly, the second semiconductor element 16 disposed on the carrier structure 13 may also be picked up, for instance, by the same stamp transfer process. In some embodiments, the first and second semiconductor elements 15 and 16 may be picked up sequentially. In other embodiments, the first and second semiconductor elements 15 and 16 may be picked up simultaneously in a single process step. It should be noted that the adhesion force of the contact protrusions 130 is preferably lower than that of the equipment using in the stamp transfer process, so as to facilitate the pickup process during stamp transfer.

As shown in FIG. 9, following the above steps, the first semiconductor element 15 is disposed on a target substrate 20. For example, the first semiconductor element 15 may be disposed on the target substrate 20 by a stamp transfer process. Similarly, the second semiconductor element 16 located on the carrier structure 13 is picked up. For example, the second semiconductor element 16 may be disposed on the target substrate 20 by a stamp transfer process, but the present disclosure is not limited thereto. In some embodiments, the first semiconductor element 15 and the second semiconductor element 16 may be disposed in sequence, but the present disclosure is not limited thereto. In other embodiments, the first semiconductor element 15 and the second semiconductor element 16 may be simultaneously disposed in the same process.

As shown in FIG. 9, in some embodiments, the target substrate 20 may be or may include a circuit board. For example, the circuit board may be a rigid circuit board, a flexible circuit board, a printed circuit board, combinations thereof, or other suitable circuit boards.

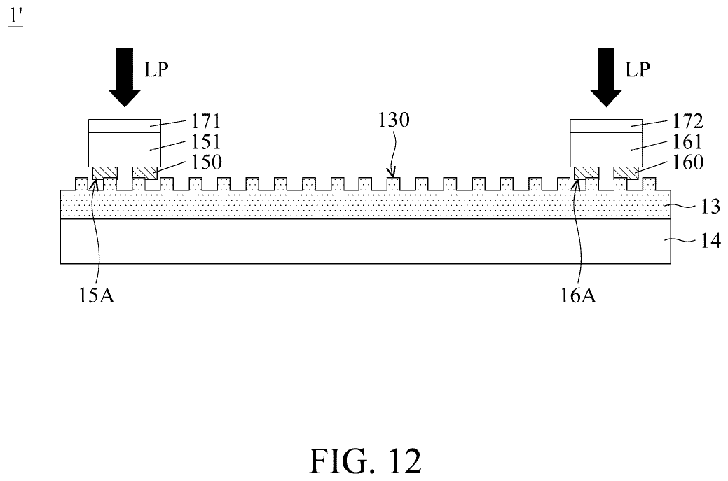

It should be noted that although the above description refers to the transfer method of the semiconductor elements (e.g., the first semiconductor element 15 and the second semiconductor element 16) as a pad-up configuration, the present disclosure is not limited thereto. In other embodiments, the semiconductor elements (e.g., the first semiconductor element 15 and the second semiconductor element 16) may alternatively be transferred in a pad-down configuration. FIGS. 12 to 14 are schematic diagrams illustrating the semiconductor carrier 1′ at different stages in the mass transfer process according to other embodiments of the present disclosure. Specifically, FIG. 12 illustrates a step following that shown in FIG. 6.

As shown in FIG. 12, following the step of FIG. 6, the first semiconductor element 15 and the second semiconductor element 16 are disposed on the carrier structure 13 such that they are in contact with the contact protrusions 130. The first electrode 150 is located between the first semiconductor stack 151 and the contact protrusions 130, and the second electrode 160 is located between the second semiconductor stack 161 and the contact protrusions 130. In other words, the first electrode 150 of the first semiconductor element 15 and the second electrode 160 of the second semiconductor element 16 may face the contact protrusions 130, that is, face downward. Meanwhile, the adhesive layer 171 remains disposed on the side of the first semiconductor element 15 opposite the carrier structure 13, and the adhesive layer 172 remains disposed on the side of the second semiconductor element 16 opposite the carrier structure 13. Specifically, the adhesive layer 171 is disposed on the first semiconductor stack 151, and the adhesive layer 172 is disposed on the second semiconductor stack 161. In some embodiments, the first semiconductor element 15 and the second semiconductor element 16 directly contact the contact protrusion 130.

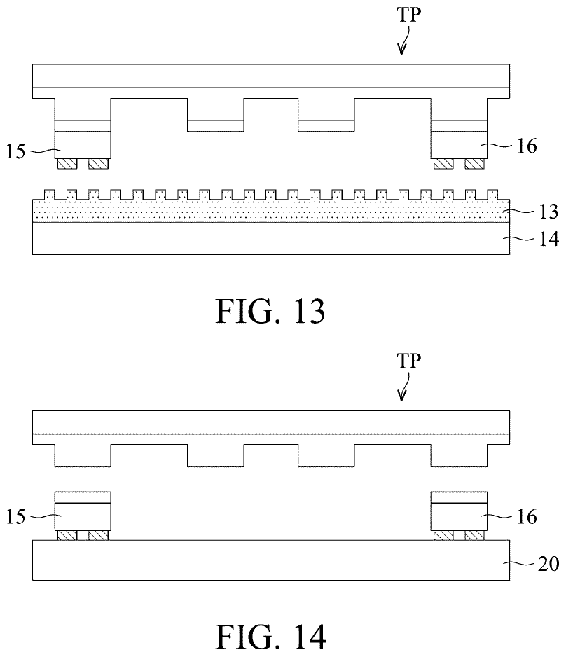

As shown in FIG. 13, following the above steps, the first semiconductor element 15 and the second semiconductor element 16 located on the carrier structure 13 are picked up. As shown in FIG. 14, following the above steps, the first semiconductor element 15 and the second semiconductor element 16 are disposed on the target substrate 20. In other words, the laser transfer process disclosed herein may be applied to both pad-down and pad-up situations.

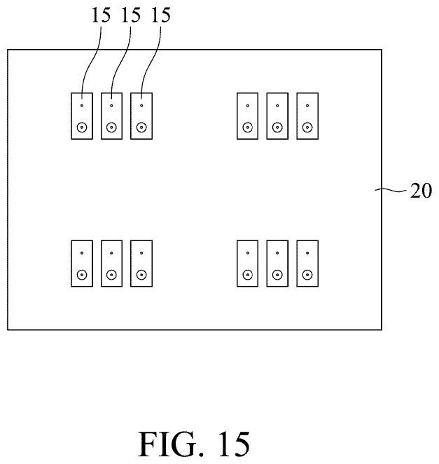

FIG. 15 illustrates possible arrangements of semiconductor elements according to some embodiments of the present disclosure. As shown in FIG. 15, in some embodiments, the first semiconductor element 15 may be a micro light-emitting diode (μLED) and may constitute a periodic light-emitting unit. Each light-emitting unit includes three first semiconductor elements 15, which respectively emit red, green, and blue visible light. It should be understood, however, that the present disclosure is not limited thereto. In other embodiments, the first semiconductor elements 15 may be arranged in alternative configurations, and are not limited to the specific arrangement illustrated in FIG. 15.

In summary, the present disclosure provides a semiconductor carrier comprising a base material, a carrier structure, and a semiconductor element. Specifically, the base material and the carrier structure together form a temporary substrate that not only temporarily supports the semiconductor element, but also facilitates easy pickup of the semiconductor element. In this manner, the present disclosure effectively addresses certain issues associated with the prior art, such as high process complexity and low yield.

Components in the disclosed embodiments may be mixed and matched arbitrarily as long as they do not violate the spirit of the invention or conflict with each other. In addition, the scope of protection of the present disclosure is not limited to the process, machine, manufacture, material composition, device, method and steps in the specific embodiments described in the specification, any person with ordinary knowledge in the field may learn from the contents of the present disclosure Understand the process, machine, manufacture, material composition, device, method and steps developed in the present or in the future, as long as they may implement substantially the same function or obtain substantially the same result in the embodiments described herein, they may be used according to the present disclosure. Therefore, the scope of protection of the present disclosure includes the above-mentioned process, machine, manufacture, composition of matter, device, method and steps. Any embodiment or claims of the present disclosure need not achieve all the objectives, advantages and/or features disclosed in the present disclosure.

The foregoing outlines features of several embodiments of the present disclosure, so that a person of ordinary skill in the art may better understand the aspects of the present disclosure. A person of ordinary skill in the art should appreciate that, the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor carrier, comprising:
a base material;
a carrier structure, disposed on the base material, and having a plurality of contact protrusions arranged in a periodical configuration; and
a first semiconductor element, disposed on the carrier structure in a configuration of contacting the plurality of contact protrusions, and having a first surface which has a first surface area SA1, and a first contact area CA1 with the plurality of contact protrusions,
wherein 0.1≤CA1/SAI<1.

2. The semiconductor carrier of claim 1, wherein the carrier structure comprises polydimethylsiloxane (PDMS).

3. The semiconductor carrier of claim 1, wherein the plurality of contact protrusions are periodically arranged in a hexagonal closest-packed (HCP) manner.

4. The semiconductor carrier as claimed in claim 3, wherein two adjacent contact protrusions of the plurality of contact protrusions are distant from each other by a pitch of between 8 μm and 17.5 μm.

5. The semiconductor carrier of claim 1, wherein at least one of the plurality of contact protrusions is formed in a cylindrical structure with a height-to-width ratio between 0.5 and 1.5.

6. The semiconductor carrier of claim 1, wherein at least one of the plurality of contact protrusions has a diameter of between 0.5 μm and 10 μm.

7. The semiconductor carrier of claim 1, wherein at least one of the plurality of contact protrusions has a height of between 1 μm and 10 μm.

8. The semiconductor carrier of claim 1, wherein at least one of the plurality of contact protrusions has an elastic recovery of between 5% and 50%.

9. The semiconductor carrier of claim 1, wherein the plurality of contact protrusions has a surface adhesion of between 6 gram-force and 60 gram-force.

10. The semiconductor carrier of claim 1, wherein the first semiconductor element is in contact with at least two of the plurality of contact protrusions.

11. The semiconductor carrier of claim 1, wherein the first semiconductor element has a first electrode and a first semiconductor stack, and the first electrode is located between the first semiconductor stack and the plurality of contact protrusions.

12. The semiconductor carrier of claim 1, wherein the first semiconductor element has a first electrode and a first semiconductor stack, and the first semiconductor stack is located between the first electrode and the plurality of contact protrusions.

13. The semiconductor carrier of claim 1, further comprising:
a second semiconductor element, different the first semiconductor element, disposed on the carrier structure in a configuration of contacting the plurality of contact protrusions, and has a second surface which has a second surface area SA2, and a second contact area CA2 with the plurality of contact protrusions,
wherein 0.1≤CA1/SAI<1.

14. The semiconductor carrier of claim 13, wherein the second semiconductor element is in contact with at least two of the plurality of contact protrusions.

15. The semiconductor carrier of claim 13, wherein the second semiconductor element has a second electrode and a second semiconductor stack, the second electrode is located between the second semiconductor stack and the plurality of contact protrusions.

16. The semiconductor carrier of claim 13, wherein the second semiconductor element has a second electrode and a second semiconductor stack, the second semiconductor stack is located between the second electrode and the plurality of contact protrusions.

17. The semiconductor carrier of claim 1, wherein each of the plurality of contact protrusions has a flat top surface.

18. The semiconductor carrier of claim 1, wherein each of the plurality of contact protrusions is formed in a cylindrical structure, a triangular prism structure, a rectangular prism structure, or a polygonal prism structure.

19. The semiconductor carrier of claim 1, wherein the plurality of contact protrusions has a contact protrusion that is adjacent to a side edge of the carrier structure and has a smaller size.

20. The semiconductor carrier of claim 19, wherein the plurality of contact protrusions has a contact protrusion that is adjacent to a center portion of the carrier structure and has a larger size.
